(19) United States
(12) Patent Application Publication
(10) Pub. No.: US 2012/0147537 A1
(43) Pub. Date: Jun. 14, 2012

(54) SYSTEM AND METHOD FOR DEPLOYMENT OF MOTION DETECTOR

(76) Inventor: Lorenzo Burgess, Orlando, FL (US)

(21) Appl. No.: 13/324,379

(22) Filed: Dec. 13, 2011

Related U.S. Application Data
(60) Provisional application No. 61/422,314, filed on Dec. 13, 2010.

(51) Int. Cl. H05K 5/00; H05B 37/02

(52) U.S. Cl. 361/679.01; 315/159

(57) ABSTRACT

A system and method for the deployment of a motion detector is disclosed. In a particular embodiment, the system includes a housing having an aperture to allow for infrared or ultrasonic sound waves to pass through to the interior of the housing. A top cap conceals the components of the motion detector inside. A receiver of the motion detector is adjacent to the aperture inside the housing and adapted to receive and register infrared or ultrasonic sound waves. A base is used to adjust the receiver inside the housing to achieve the desired zone of detection. A transmitting antennae is also built into the motion detector within the housing that is used to transmit a signal to a receiver that is remotely located.

### I. CROSS REFERENCE TO RELATED APPLICATIONS

This application claims the benefit of U.S. provisional patent application Ser. 61/422,314 filed Dec. 13, 2011.

### II. FIELD OF THE INVENTION

The present invention relates in general to a system and method for deployment of a motion detector.

### III. BACKGROUND

Motion detectors are used to detect the movement of objects within a zone of view. The zone of view is generally circumscribed by an arc shape and up to a distance of 50 to 80 feet. Accordingly, any object that moves within the zone of view may be registered by the motion detector sensor and trigger an alarm or lights, for example.

A motion detector may be active or passive. An active sensor emits energy, usually ultrasonic sound waves, into the zone of view. In contrast, passive sensors sense changes in the energy using a predetermined baseline energy level in the surrounding area.

An active sensor transmits bursts of ultrasonic sound waves then waits for the sound waves to be reflected back and received. If the active sensor does not detect that the sound wave was reflected back, then the sensor registers an object must be in the zone of view and triggers the alarm. Passive motion detectors are more commonly used to secure businesses and residential homes than active motion sensors. Passive sensors use infrared energy to determine motion within a zone of view. Any body, including animals and humans, will emit infrared energy because they create heat. The amount emitted depends on the temperature of the body, but in humans, it is usually between 9 and 10 micrometers.

Most passive sensors detect emissions in the range of 8 to 12 micrometers. The passive sensor coverts light in these wavelengths into an electrical current, which is processed by an integrated circuit. The alarm is triggered when the passive sensor detects large or fast variations in the distribution of the emitted infrared energy. Accordingly, a human creates variations in the infrared energy that is readily detected by a passive sensor.

In a residential application, the motion detector is secured to the residence and faces outwards. Thus, often times small animals such as dogs or squirrels may inadvertently activate the motion sensor. If the motion sensor is wired to a light source, for example, the light is mistakenly is illuminated every time an animal walks by creating false alarms. Accordingly, there is a need in the art for a system and method for deployment of a motion detector that eliminates false alarms and provides increased reliable coverage for a residence or business.

However, in view of the prior art at the time the present invention was made, it was not obvious to those of ordinary skill in the pertinent art how the identified needs could be fulfilled.

### IV. SUMMARY

The following presents a simplified summary of one or more embodiments in order to provide a basic understanding of some aspects of such embodiments. This summary is not an extensive overview of the one or more embodiments, and is intended to neither identify key or critical elements of the embodiments nor delineate the scope of such embodiments. Its sole purpose is to present some concepts of the described embodiments in a simplified form as a prelude to the more detailed description that is presented later.

A system and method for the deployment of a motion detector is disclosed. In a particular embodiment, the system includes a housing having an aperture to allow for infrared or ultrasonic sound waves to pass through to the interior of the housing. A top cap conceals the components of the motion detector inside. A receiver of the motion detector is adjacent to the aperture inside the housing and adapted to receive and register infrared or ultrasonic sound waves. A base is used to adjust the receiver inside the housing to achieve the desired zone of detection. A transmitting antennae is also built into the motion detector within the housing that is used to transmit a signal to a receiver that is remotely located.

In another particular embodiment, a method for the deployment of a motion detector is disclosed. The method includes establishing a zone of detection between a motion detector and a front entranceway and windows of a house, where the zone of detection excludes areas where cars, pedestrians, animals, or any combination thereof are most likely to be moving through in the ordinary course of everyday activities. In addition, the method includes mounting at least one floodlight to at least one corner of the house, where the floodlight is in electrical communication via radio frequency waves (RF) (or ultrasonic) with the motion detector. The method also includes detecting movement within the zone of detection, transmitting an RF signal using a transmitting antennae, receiving the RF signal at the floodlight using a receiving antennae, and activating the floodlight upon receiving a signal from the motion detector, where the floodlight is activated and turned on for a predetermined amount of time.

To the accomplishment of the foregoing and related ends, one or more embodiments comprise the features hereinafter fully described and particularly pointed out in the claims. The following description and the annexed drawings set forth in detail certain illustrative aspects and are indicative of but a few of the various ways in which the principles of the embodiments may be employed. Other advantages and novel features will become apparent from the following detailed description when considered in conjunction with the drawings and the disclosed embodiments are intended to include all such aspects and their equivalents.

### V. BRIEF DESCRIPTION OF THE DRAWINGS

FIG. 1 is a perspective view of a particular illustrative embodiment of system for the deployment of a motion detector;

FIG. 2 is a partial exploded view of the system for the deployment of the motion detector;

FIG. 3 is top view of the system for deployment of the motion detector shown with the cap removed;

FIG. 4 is a bottom view of the system for deployment of the motion detector;

FIG. 5 is a side view of the system for deployment of the motion detector;

FIG. 6 is a rear view of the system for deployment of the motion detector;

FIG. 7 a particular illustrative embodiment of method for the deployment of a motion detector; and

FIG. 8 is a particular illustrative embodiment of the system and method for the deployment of a motion detector in operation.

### VI. DETAILED DESCRIPTION

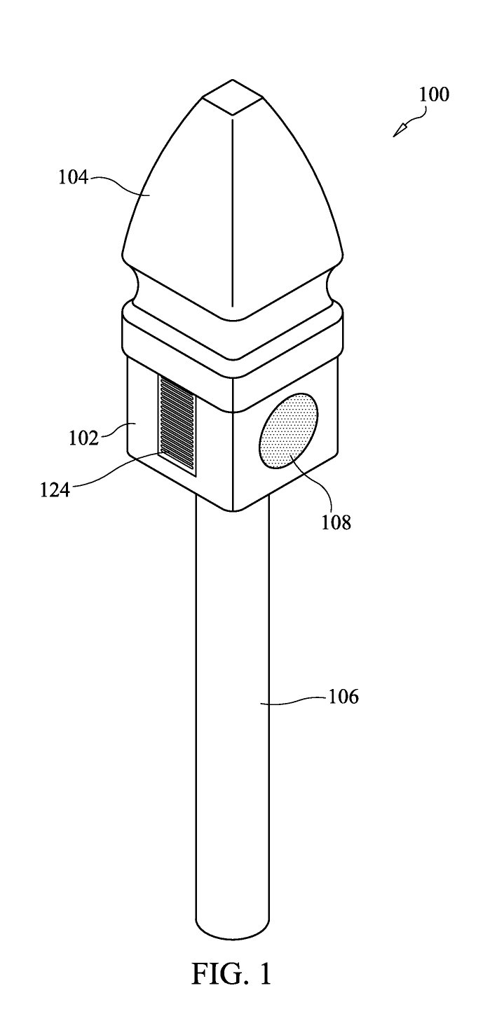

In a particular illustrative embodiment of the system for the deployment of a motion detector, the system is generally designated 100. Referring now to FIG. 1, the system 100 includes a housing 102, a cap 104, and a mounting post 106. The system 100 is not required to be mounted on the post 106 but could be mounted to another fixed object, such as a fence, or tree, for example. An aperture 108 of the housing 102 allows for infrared or ultrasonic sound waves to pass through to the interior of the housing 102 in operation of the system 100 but also to conceal the contents of the housing 102.

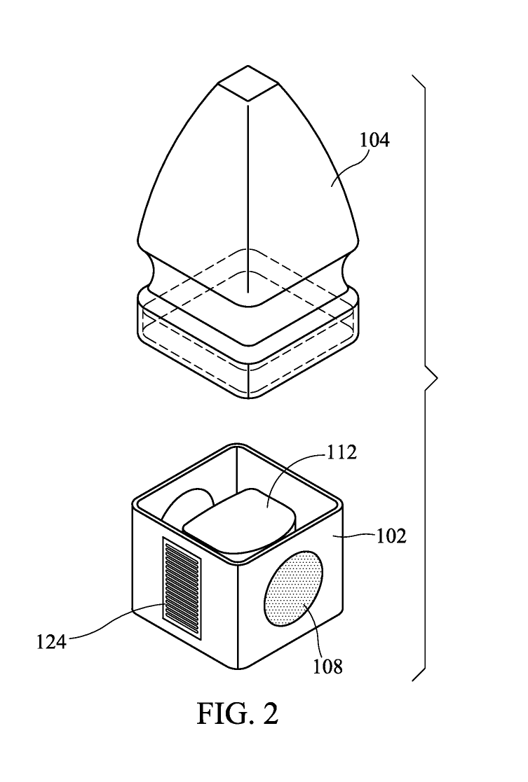

Referring now to FIG. 2, the top cap 104 is removed showing the top portion of the housing 102 and components of the motion detector 112 are visible. The cap 104 is placed over the housing 102 to seal the system 100.

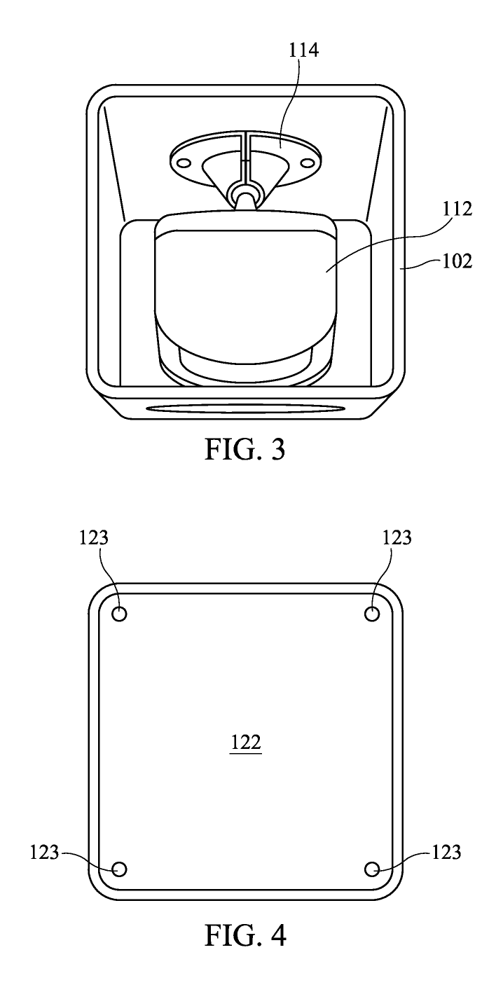

The motion detector 112 is adjacent to the aperture 108 inside the housing 102, as shown in FIG. 3. A base 114 is used to adjust the motion detector 112 inside the housing 102 to achieve the desired zone of detection. A transmitting antennae is built into the motion detector within the housing 102 that is used to transmit a signal, typically an RF signal, to a receiver that is remotely located. For example, the receiver may be mounted to a corner of a residence and upon receiving a signal from the transmitting antennae, activates the lights or alarm to turn on.

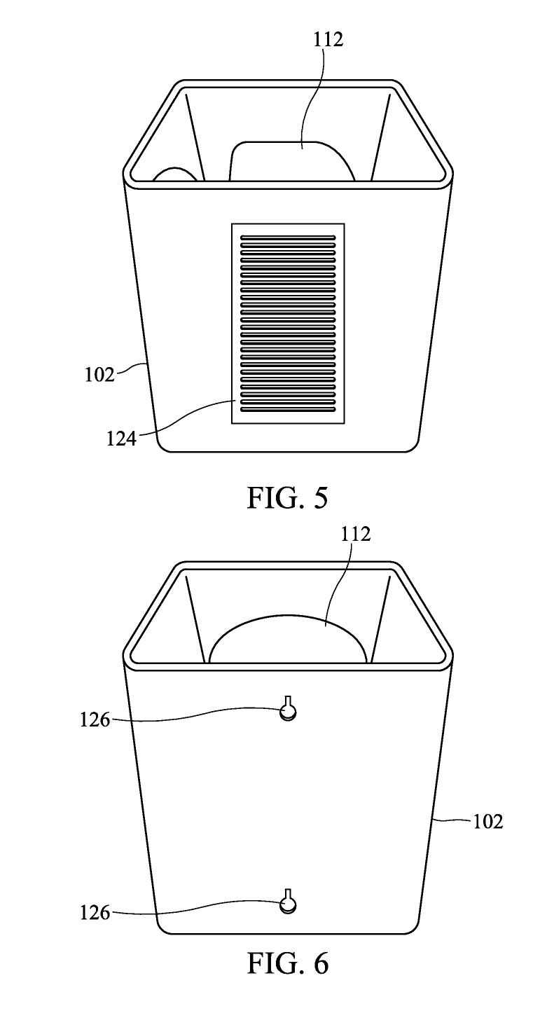

The bottom of the housing 102, as shown in FIG. 4, may include a plurality of drain holes to allow any moisture that enters the housing 102 to drain out and to otherwise ventilate the housing 102. In addition, vents 124 may be included on the sides of the housing 102 to provide additional ventilation to the components of the motion detector 112, as shown in FIG. 5. The rear side of the housing 102, may include mounting holes 126, as shown in FIG. 6. The mounting holes 126 would be used when mounting the system 100 to a vertical surface.

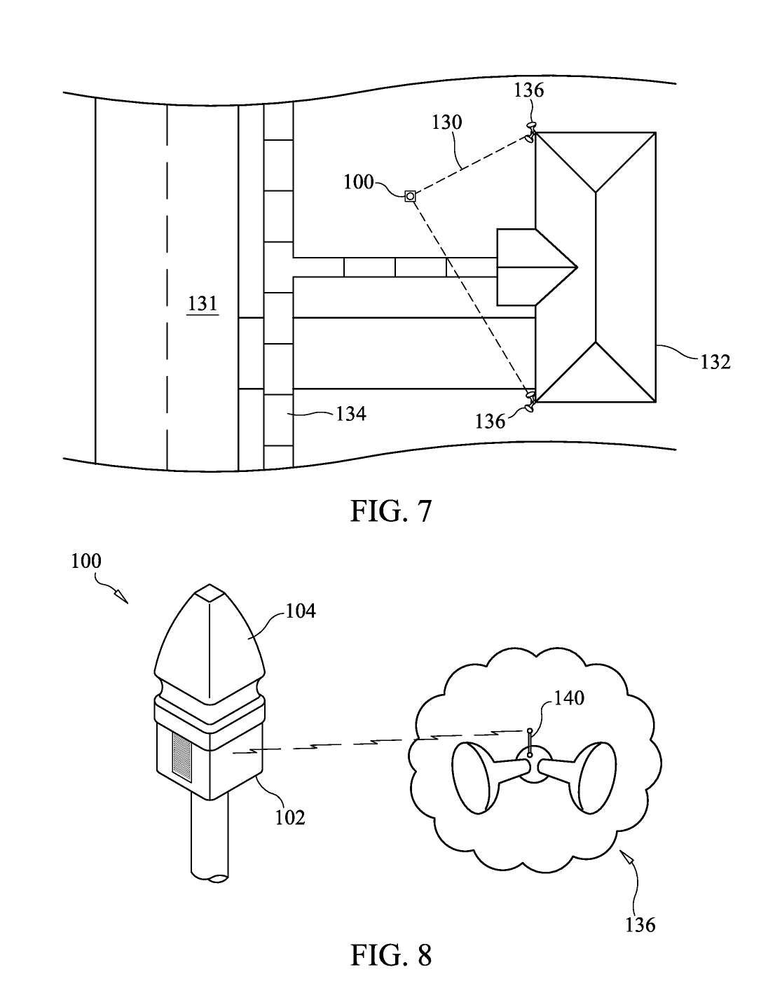

Referring now to FIG. 7, a particular embodiment of a method for the deployment of a motion detector is illustrated. The system 100 is located in a front of the house 132, where the motion detector is facing towards the house 132. Accordingly, the zone of detection 130 covers the front entranceway and windows on the front of the house 132. As can be seen from FIG. 7, the zone of detection does not include the street 131 or sidewalk 134 areas where cars, pedestrians, dogs, cats and other animals are most likely to be moving through in the ordinary course of everyday activities. Floodlights 136 are mounted to the corners of the house 132 and are in electrical communication via radio frequency waves (RF) with the system 100.

In operation, the motion detector 112 of the system 100 detects movement within the zone of detection 130. This triggers an RF signal to be transmitted using the transmitting antennae 120. The RF signal is received at the floodlight 136 using receiving antennae 140. Upon receiving a signal from the motion detector 112, the floodlights are activated and turned on for a predetermined amount of time. The lights may automatically turn off and the system is rest after the predetermined amount of time has lapsed.

An advantage of the system is that it is concealed whereas typically motion detectors are readily detectable. Accordingly, the system provides additional security as an intruder will not be aware that the motion detector is present and cannot avoid detection.

Another particular advantage of the system is that the system may be placed anywhere and is adaptable to remotely transmit a signal to any type of alarm, light or other notification means such as cell phone. The system can be placed facing towards the house or along a vulnerable side of doorway to provide coverage to detect any motion.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

What is claimed is:

1. A system for deployment of a motion detector, the system comprising:
a housing to contain the motion detector, wherein the housing is configured to be mounted to a fixed object;
a removable cap configured to fit over an upper end of the housing to seal the housing; and
an aperture of the housing allows for infrared or ultrasonic sound waves, or any combination thereof to pass through to an interior of the housing;

2. The system of claim 1, wherein the housing is mounted to a post, a fence, a tree, or any combination thereof.

3. The system of claim 2, wherein a motion detector sensor of the motion detector is adjacent to the aperture inside the housing.

4. The system of claim 3, the motion detector further comprising an adjustable base to adjust the motion detector inside the housing to achieve a desired zone of detection.

5. The system of claim 4, the motion detector configured to transmit a wireless signal.

6. The system of claim 5, further comprising a remotely located receiver configured to receive the wireless signal to activate an alarm, lights, or any combination thereof.

7. The system of claim 6, wherein the receiver is configured to mount to a corner of a residence.

8. The system of claim 7, a bottom of the housing further comprising a plurality of drain holes to ventilate the housing and to allow any moisture that enters the housing to drain out.

9. The system of claim 8, at least one side of the housing further comprising vents to ventilate components of the motion detector.

10. The system of claim 9, a rear side of the housing further comprising mounting holes to mount the housing to a vertical surface.

11. The system of claim 10, wherein the motion detector sensor is placed in front of the residence and facing towards the residence.

12. The system of claim 4, wherein the signal is configured to transmit to a cell phone.

13. A method for the deployment of a motion detector, the method comprising:
establishing a zone of detection between a motion detector and a front entranceway and windows of a house, wherein the zone of detection excludes areas where cars, pedestrians, animals, or any combination thereof are most likely to be moving through in the ordinary course of everyday activities;
mounting at least one floodlight to at least one corner of the house, wherein the floodlight is in electrical communication via radio frequency waves (RF) with the motion detector;
detecting movement within the zone of detection;
transmitting an RF signal using a transmitting antennae;
receiving the RF signal at the floodlight using a receiving antennae;
activating the floodlight upon receiving a signal from the motion detector, wherein the floodlight is activated and turned on for a predetermined amount of time.

14. The method of claim 13, wherein the floodlight automatically turns off after the predetermined amount of time has lapsed.

15. A method for the deployment of a motion detector, the method comprising:
placing a free standing motion detector to establish a zone of detection between the motion detector and a building;
monitoring movement within the zone of detection;
transmitting a wireless signal from the motion detector when motion is detected;
receiving the wireless signal at a remote location from the motion detector; and
activating a floodlight upon receiving the signal from the motion detector.
